(19) United States
(12) Patent Application Publication
(10) Pub. No.: US 2019/0103357 A1
(43) Pub. Date: Apr. 4, 2019

(54) METHODS OF FORMING PACKAGE ON PACKAGE ASSEMBLIES WITH REDUCED Z HEIGHT AND STRUCTURES FORMED THEREBY

(71) Applicant: Intel Corporation, Santa Clara, CA (US)

(72) Inventors: Min Suet Lim, Bayan Lepas (MY); Eng Huat Goh, Ayer Itam (MY); Khang Choong Yong, Puchong (MY); Wil Choon Song, Bayan Lepas (MY); Jiun Hann Sir, Gelugor (MY); Boon Ping Koh, Seberang Jaya (MY)

(73) Assignee: Intel Corporation, Santa Clara, CA (US)

(21) Appl. No.: 15/720,393

(22) Filed: Sep. 29, 2017

(51) Int. Cl. H01L 23/538; H01L 23/31; H01L 25/065; H01L 23/498; B81C 1/00; H01L 23/48; H01L 23/00

(52) U.S. Cl. CPC H01L 23/5384; H01L 23/3121; H01L 25/0657; H01L 23/49811; H01L 24/49; H01L 23/481; H01L 23/49838; H01L 24/13; H01L 24/16; B81C 1/00301

(57) ABSTRACT

Methods/structures of joining package structures are described. Those methods/structures may include a first package, wherein the first package includes a first substrate section and a second substrate section. A plurality of stacked die may be disposed between the first substrate section and the second substrate section, wherein a surface of a first die of the plurality of stacked die is coplanar with a surface of the first section and with a surface of the second section. A second package is physically and electrically coupled to the first package.

### BACKGROUND

The assembly processes utilized in the assembly of microelectronic package structures, such as package on package (PoP) structures, for example, can be a fabrication challenge for electronic manufacturers. Such issues as package Z height optimization, impedance mismatch between die, and on-chip hot spots can impact package performance.

### BRIEF DESCRIPTION OF THE DRAWINGS

While the specification concludes with claims particularly pointing out and distinctly claiming certain embodiments, the advantages of these embodiments can be more readily ascertained from the following description when read in conjunction with the accompanying drawings in which:

FIG. 1a represent cross-sectional views of a package structure according to embodiments. FIG. 1b represents a top view of a package structures according to embodiments. FIGS. 1c-1f represent cross-sectional views of package structures according to embodiments.

FIGS. 2a-2h represents cross-sectional views of methods of forming package structures according to embodiments.

FIG. 3a represents a cross-sectional view of package structures according to embodiments. FIG. 3b depicts a table according to embodiments. FIG. 3c depicts a cross-sectional view of package structures according to embodiments. FIG. 3d depicts a table according to embodiments.

FIG. 4 represents a flow chart of a method of forming package structures according to embodiments.

FIG. 5 represents a schematic of a computing device according to embodiments.

In the following detailed description, reference is made to the accompanying drawings that show, by way of illustration, specific embodiments in which the methods and structures may be practiced. These embodiments are described in sufficient detail to enable those skilled in the art to practice the embodiments. It is to be understood that the various embodiments, although different, are not necessarily mutually exclusive. For example, a particular feature, structure, or characteristic described herein, in connection with one embodiment, may be implemented within other embodiments without departing from the spirit and scope of the embodiments. In addition, it is to be understood that the location or arrangement of individual elements within each disclosed embodiment may be modified without departing from the spirit and scope of the embodiments.

The following detailed description is, therefore, not to be taken in a limiting sense, and the scope of the embodiments is defined only by the appended claims, appropriately interpreted, along with the full range of equivalents to which the claims are entitled. In the drawings, like numerals may refer to the same or similar functionality throughout the several views. The terms “over”, “to”, “between” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers. Layers and/or structures “adjacent” to one another may or may not have intervening structures/layers between them. A layer(s)/structure(s) that is/are directly on/directly in contact with another layer(s)/structure(s) may have no intervening layer(s)/structure(s) between them.

Various implementations of the embodiments herein may be formed or carried out on a substrate, such as a package substrate. A package substrate may comprise any suitable type of substrate capable of providing electrical communications between a die, such as an integrated circuit (IC) die, and a next-level component to which an microelectronic package may be coupled (e.g., a circuit board). In another embodiment, the substrate may comprise any suitable type of substrate capable of providing electrical communication between an IC die and an upper IC package coupled with a lower IC/die package, and in a further embodiment a substrate may comprise any suitable type of substrate capable of providing electrical communication between an upper IC package and a next-level component to which an IC package is coupled.

A substrate may also provide structural support for a die/device. By way of example, in one embodiment, a substrate may comprise a multi-layer substrate—including alternating layers of a dielectric material and metal—built-up around a core layer (either a dielectric or a metal core). In another embodiment, a substrate may comprise a coreless multi-layer substrate. Other types of substrates and substrate materials may also find use with the disclosed embodiments (e.g., ceramics, sapphire, glass, etc.). Further, according to one embodiment, a substrate may comprise alternating layers of dielectric material and metal that are built-up over a die itself—this process is sometimes referred to as a “bumpless build-up process.” Where such an approach is utilized, conductive interconnects may or may not be needed (as the build-up layers may be disposed directly over a die, in some cases).

A die/device may comprise any type of integrated circuit device. In one embodiment, the die may include a processing system (either single core or multi-core). For example, the die may comprise a microprocessor, a graphics processor, a signal processor, a network processor, a chipset, etc. In one embodiment, a die may comprise a system-on-chip (SoC) having multiple functional units (e.g., one or more processing units, one or more graphics units, one or more communications units, one or more signal processing units, one or more security units, etc.). However, it should be understood that the disclosed embodiments are not limited to any particular type or class of devices/die.

Conductive interconnect structures may be disposed on a side(s) of a die/device, and may comprise any type of structure and materials capable of providing electrical communication between a die/device and a substrate, or another die/device, for example. In an embodiment, conductive interconnect structures may comprise an electrically conductive terminal on a die (e.g., a pad, bump, stud bump, column, pillar, or other suitable structure or combination of structures) and a corresponding electrically conductive terminal on a substrate (e.g., a pad, bump, stud bump, column, pillar, or other suitable structure or combination of structures). Solder (e.g., in the form of balls or bumps) may be disposed on the terminals of the substrate and/or die/device, and these terminals may then be joined using a solder reflow process. Of course, it should be understood that many other types of interconnects and materials are possible (e.g., wirebonds extending between a die and a substrate).

The terminals on a die may comprise any suitable material or any suitable combination of materials, whether disposed in multiple layers or combined to form one or more alloys and/or one or more intermetallic compounds. For example, the terminals on a die may include copper, aluminum, gold, silver, nickel, titanium, tungsten, as well as any combination of these and/or other metals. In other embodiments, a terminal may comprise one or more non-metallic materials (e.g., a conductive polymer). The terminals on a substrate may also comprise any suitable material or any suitable combination of materials, whether disposed in multiple layers or combined to form one or more alloys and/or one or more intermetallic compounds.

For example, the terminals on a substrate may include copper, aluminum, gold, silver, nickel, titanium, tungsten, as well as any combination of these and/or other metals. Any suitable solder material may be used to join the mating terminals of the die and substrate, respectively. For example, the solder material may comprise any one or more of tin, copper, silver, gold, lead, nickel, indium, as well as any combination of these and/or other metals. The solder may also include one or more additives and/or filler materials to alter a characteristic of the solder (e.g., to alter a reflow temperature).

Embodiments of methods of forming packaging structures, such as methods of forming a plurality of stacked die in a central portion of a package substrate to reduce overall package Z height, are described. Those methods/structures may include providing a first package, wherein the first package includes a plurality of stacked die, wherein a first die of the plurality is disposed adjacent a first side of a molding compound. A first section of a substrate may be disposed on the first side of the molding compound, and a second section of the substrate may be disposed on the first side of the molding compound, wherein the plurality of stacked die is disposed between the first section and the second section of the substrate. The embodiments herein enable the formation of package on package (PoP) assemblies which comprise a reduced Z height, minimize memory die impedance mismatch, and reduce local hot spots within stacked memory die, for example.

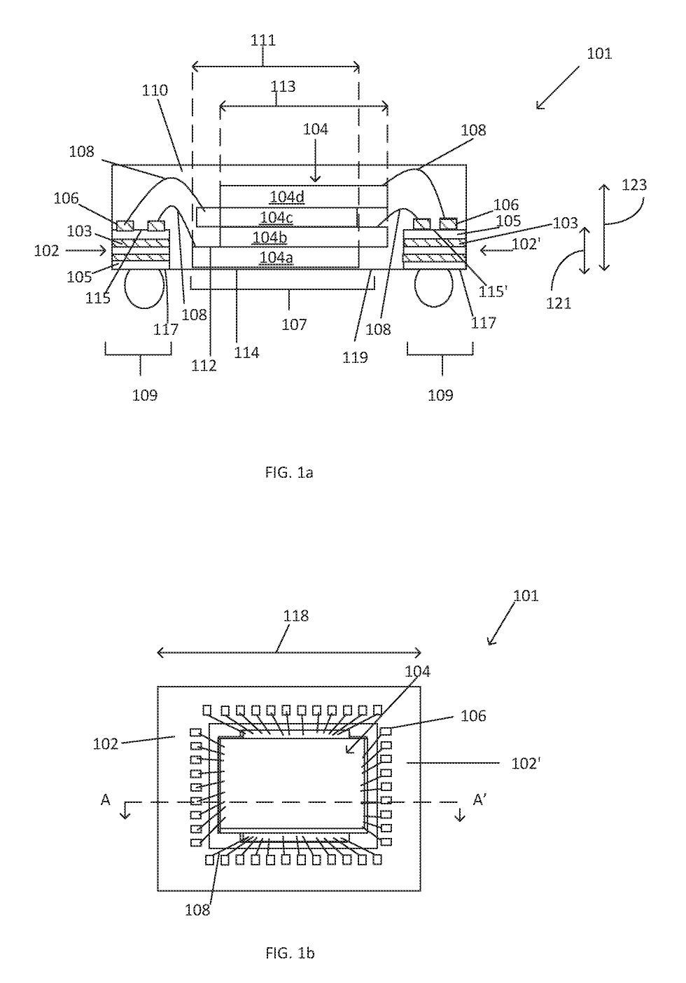

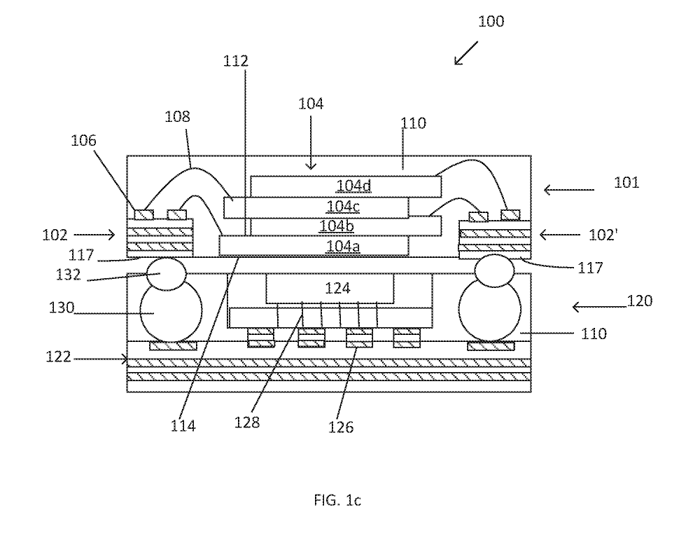

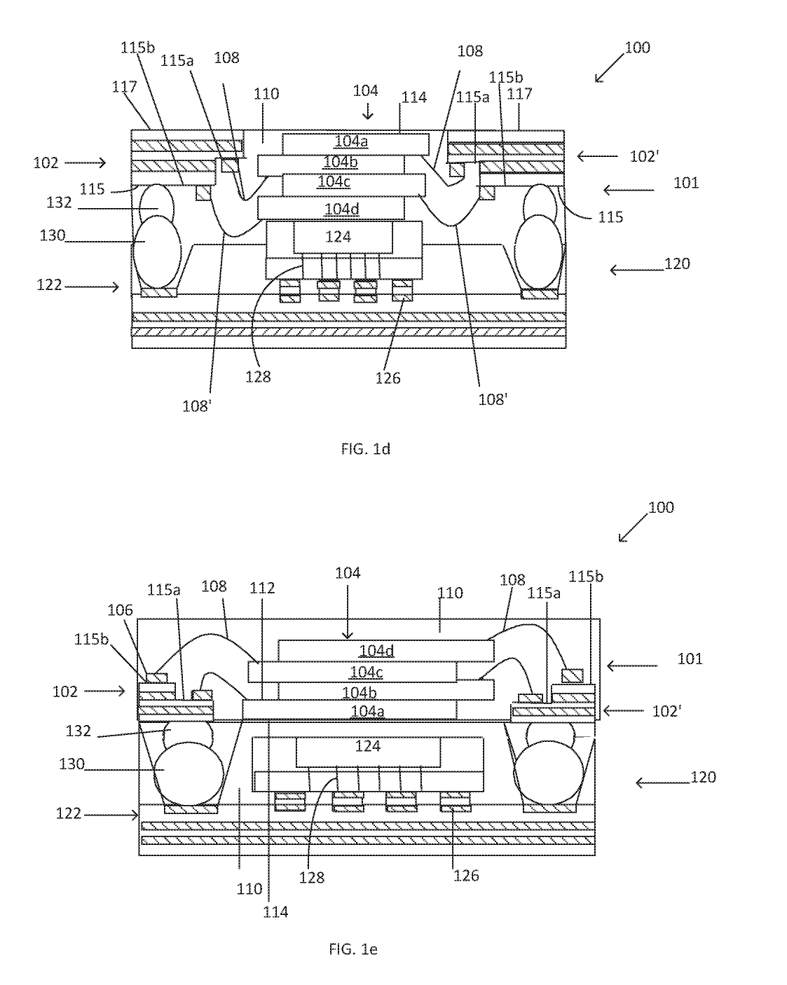

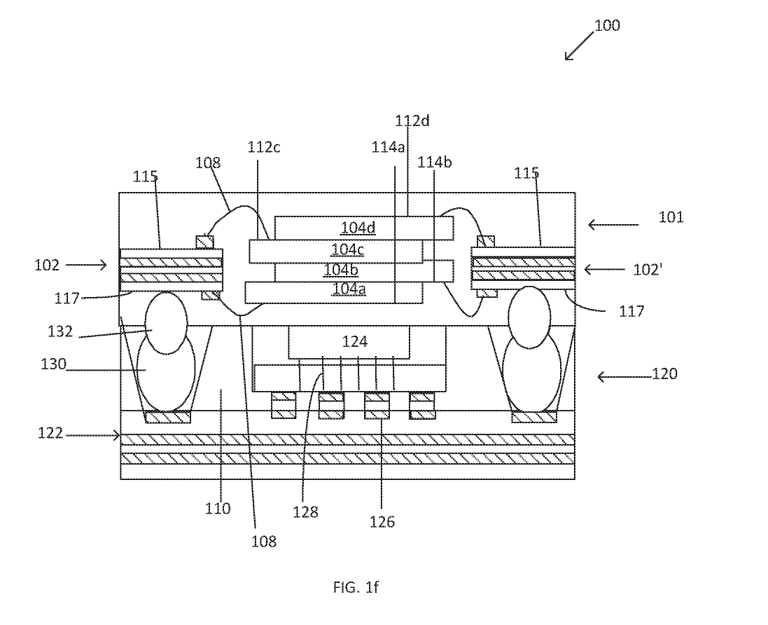

FIGS. 1a-1f illustrate embodiments of fabricating package structures/assembles comprising a reduced Z height, for example. In FIG. 1a (cross-sectional view), a portion of a package structure 101, which may comprise a lower portion/package of a package on package (PoP) assembly, may include a first section of a substrate 102, and a second section of a substrate 102′. The first and second sections of the substrate 102, 102′ may comprise alternating layers of dielectric 103 and conductive material/layers 105, wherein the first section 102 and the second section 102′ may be located in peripheral portions 109 of the first package 101. The conductive layers 103 may comprise routing signals, such as 10 signals, Vss and Vcc power planes, for example. The first package 101 may further comprise a plurality of stacked die 104 located in a central portion/region 107 of the first package 101, and may be located between the first section 102 and the second section 102′.

The plurality of stacked die 104 may comprise a first die 104a stacked upon a second die 104b that is stacked upon a third die 104c that is stacked upon a fourth die 104d, in an embodiment. The number and types of die 104 that may be stacked/disposed upon each other may vary according to the particular application. In an embodiment, the plurality of die 104 may comprise memory die, such as dynamic random access memory (DRAM) die, but in other embodiments the die may comprise any other suitable type of die. In an embodiment, various footprints of the individual die may differ in size from each other, and may be offset from each other in a staggered fashion. For example the first and third die 104a, 104c may possess footprints 111 which are substantially vertically aligned with each other, while the second and fourth die 104b, 104d may comprise footprints 113 that may be offset from the footprints 111 of the first and third die 104a, 104c. The location/footprints of each of the plurality of die 104 may occupy any number of configurations, according to the particular application.

Each of the individual die of the plurality of stacked die 104 may comprise at least one wirebond conductive interconnect structure 108 that may be coupled to at least one of the first and second substrate sections 102, 102′. In an embodiment, each of the first and second substrate sections 102, 102′ comprises a plurality of conductive interconnect structures/pads 106 disposed on a first sides 115, 115′ of each of the substrate sections 102, 102′ respectively. The wirebond structures 108 of each die may be physically and electrically coupled to at least one of the conductive interconnect pads 106. In one embodiment, wirebond structures 108 of the first and third die 104a, 104c may be coupled to conductive pads 106 disposed on the first section of the substrate 102, while wirebond structures 108 disposed on the second and fourth die 104b, 104d may be coupled to the conductive pads 106 disposed on the second section of the substrate 102′.

A molding compound 110 may be disposed on the first and second sections 102, 102′ of the substrate, and may be disposed on the plurality of stacked die 104. In an embodiment, the first die 104a may comprise a first side 112 and a second side 114 opposite the first side 112. In an embodiment, the second side 114 of the first die 104a of the plurality of stacked die 104 may be adjacent and coplanar with the first side of the molding compound 119. Second sides 117, 117′ of the first and second substrate sections 102, 102′ may be disposed adjacent the plurality of stacked die 104. In an embodiment, the bottom surface/second side 114 of the first die 104a and the second sides 117, 117′ of the first and second sections 102, 102′ of the substrate may be substantially coplanar with respect to each other. In an embodiment, a height 121 of the first or second substrate sections 102, 102′ may not exceed a height 123 of the stacked die 104.

FIG. 1b is a top view of the first package 101 (FIG. 1a is a cross-sectional view of FIG. 1b through points A-A′). The plurality of stacked die 104 are disposed in a central region of the first package 101, wherein the die may comprise wirebond structures 108 to physically and electrically couple the individual die of the die stack 104 to a conductive pad 106 disposed on the first and second sections 102, 102′ of the substrate. The first and second sections 102, 102′ are located peripherally around the stacked die 104. Neither the first section 102 or the second section 102′ extend across a length 118 of the package 101, i.e. the substrate sections 102, 102′ are discontinuous across the substrate length 118.

FIG. 1c depicts a cross-sectional view of an embodiment in which a second package 120 is attached to the first package 101. Solder balls 132 disposed on and electrically coupled to the first and second substrate sections 102, 102′ are joined/mated with solder balls 132 disposed on and electrically coupled to a second package substrate 122. The solder balls 130, 132 may be undergo a subsequent attachment/reflow process, such as a surface mount technology process (SMT) for example, wherein the solder balls 130, 132 may undergo temperature cycling at above about 200 degrees Celsius, to form a solder joint between the first and second packages 101, 120. The joined first and second packages 101, 120 may comprise a package on package (POP) assembly 100. In an embodiment, the first die 104a may be disposed on/over a die 124 disposed on/within the second package 120.

The second package die 124, may comprise a system on a chip, or a central processing unit (CPU), for example, but may comprise any other suitable type of die. The second package 120 may comprise a plurality of through silicon vias (TSV) 128, that may electrically and physically couple the second package die 124 to the substrate 122. The second package substrate 122 may further comprise conductive interconnect structures 126 that may electrically couple the die 124 to the second package substrate 122. The die 124 and the solder balls 130 of the second package 120 may be at least partially embedded in a molding compound 110. In an embodiment the solder ball 132 may comprise a through mold interconnect (TMI) solder ball 132. The package structure 100 of FIG. 1c exhibits reduced impedance, since the wirebond 108 lengths are reduced due to the shorter distance to the substrate sections 102, 102′ as compared to when the die are disposed directly on a substrate, as in the prior art.

FIG. 1d depicts another embodiment of a package assembly 100, wherein the fourth die 104d of the first package 101 is disposed on/over the die 124 of the second package 120. The second side 114 of the first die 104a is substantially coplanar with the second sides 117 of the first and second sections 102, 102′ of the substrate. Wirebonds 108, 108′ may couple the first and third die 104a, 104c to the first sides 115a, 115b of the second section 102′ of the substrate. The first sides 115a, 115b of the first and second sections 102, 102′ may be opposite the second sides 117 of the first and second sections 102, 102′ of the substrate respectively. In an embodiment, at least one of the first section 102 or the second section 102′ may comprise a stepped structure, wherein the substrate may comprise a series of steps to facilitate wire bond placement within the first package 101, in order to reduce impedance.

For example, the first die 104a may comprise a wirebond coupled to a first step 115a of the second section 102′, and the third die 104c may be comprise a wirebond coupled to a second step 115b of the second section 102′, wherein the second step 115b is closer to the third die 104c than the first step 115a. In an embodiment, the stepped structure results in a shorter wire bond length for the stacked die comprising offset footprints. Solder balls 130, 132 may form a joint between the first package 101 and the second package 120 during a subsequent reflow process. Wirebonds 108 may couple the second and fourth die 104b, 104d to first sides/steps 115a, 115b of the first section 102 of the substrate. In an embodiment, the first section 102 may comprise a stepped structure, wherein the series of steps facilitate wire bond placement within the first package 101. The first sides 115a, 115b of the steps are opposite the second side 117 of the first section 102.

In another embodiment, (FIG. 1e, cross-sectional view) a package assembly 100 is depicted, wherein the first die 104a of the first package 101 is disposed on/over the die 124 of the second package 120. The second side 114 of the first die 104a is substantially coplanar with the second sides 117 of the first and second sections 102, 102′ of the substrate. Wirebonds 108 may couple the first and third die 104a, 104c to contacts 106 disposed on first sides 115a, 115b of the first section 102 of the substrate. In an embodiment, at least one of the first section 102 or the second section 102′ may comprise a stepped structure, wherein the substrate may comprise a series of steps to facilitate wire bond placement within the first package. In an embodiment, the stepped structure results in a shorter wire bond length for the stacked die comprising offset footprints.

Solder balls 130, 132 may form a joint between the first package 101 and the second package 120 during a subsequent reflow process. Wirebonds 108 may couple the second and fourth die 104b, 104d to first sides/steps 115a, 115b of the second section 102′ of the substrate. In an embodiment, the second section 102′ may comprise a stepped structure, wherein the substrate may comprise a series of steps to facilitate wire bond placement within the first package.

In another embodiment, (FIG. 1f, cross-sectional view) a package assembly 100 is depicted, wherein the first die 104a of the first package 101 is disposed on/over the die 124 of the second package 120. The second side 114a of the first die 104a is substantially coplanar with the second sides 117 of the first and second sections 102, 102′ of the substrate. A wirebond structure 108 may electrically and physically couple the second side 114a of the first die 104a to the second side 117 of the first section 102 of the substrate, and a wirebond structure 108 may electrically and physically couple a first side 112c of the third die 104c to a first side 115 of the first section 102 of the substrate.

A wirebond structure 108 may electrically and physically couple the second side 114b of the second die 104b to a second side 117 of the second section 102′ of the substrate, and a wirebond structure 108 may electrically and physically couple a first side 112d of the fourth die 104d to a first side of the second section 102′ of the substrate. Solder balls 130, 132 may form a joint between the first package 101 and the second package 120 during a subsequent reflow process.

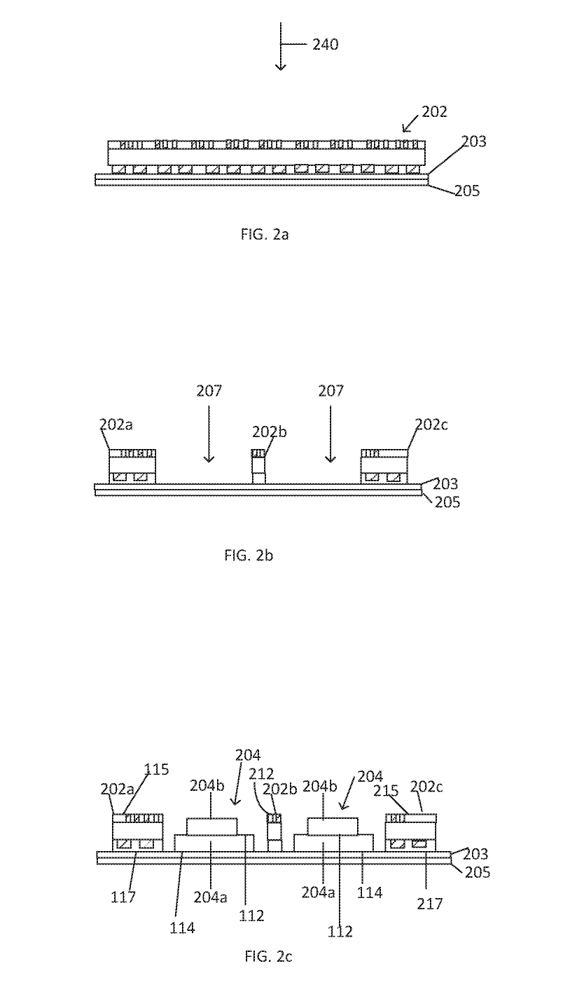

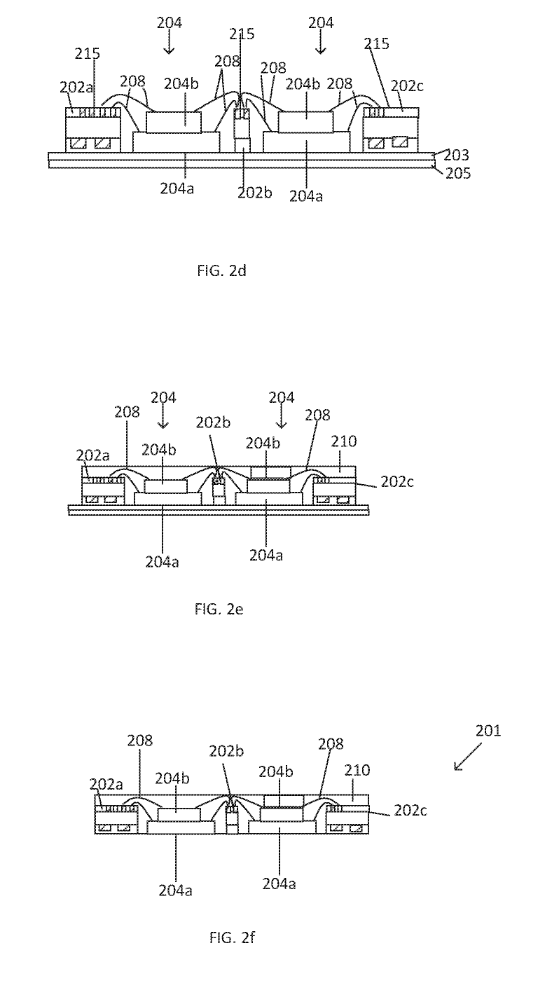

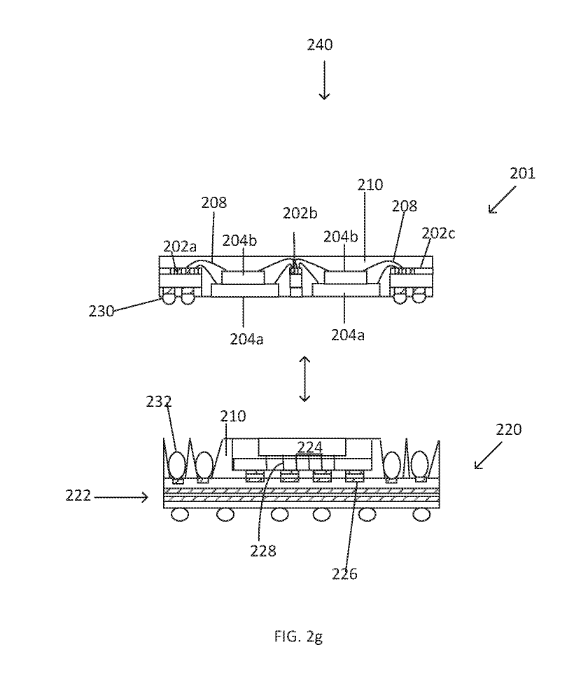

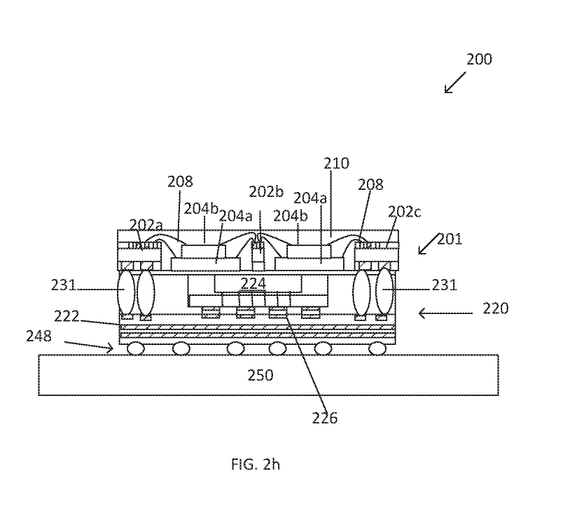

In FIGS. 2a-2g, a method of fabricating the POP package of the embodiments herein is described. In FIG. 2a, a substrate 202 may be provided comprising conductive material separated by dielectric material. The substrate 202 may be disposed on a carrier, such as a polyethylene terephthalate (PET) 203 film disposed on a glass material 205, for example. In FIG. 2b, openings 207 are formed in the substrate 202, wherein the substrate 202 may comprise a panel in an embodiment. The substrate 202 may comprise sections, such as sections 202a, 202b, 202c, and so on across the panel, with openings 207 separating the sections of the substrate 202. In FIG. 2c, a plurality of stacked die 204 may be placed within each of the openings 207 between sections of the substrate 202. The plurality of stacked die 204 may comprise at least two die, but may comprise any number of die stacked upon each other. In an embodiment, the plurality of stacked die 204 may comprise a plurality of DRAM memory die. The plurality of die 204 may be placed directly on the PET, wherein a first die 204a may comprise a first side 212 and a second side 214, wherein the second side(s) 214 of the first die(s) 204a may be coplanar with second sides 217 (that are opposite first sides 215) of the substrate sections 202a, 202b, 202c.

In FIG. 2d, wirebonding is performed to physically and electrically couple individual die 204a, 204b of the plurality of stacked die 204 to sections of the substrate 202a, 202b, 202c, wherein wirebond conductive structures 208 may be connected/bonded between individual die and substrate sections. FIG. 2d depicts the wirebonds coupled to the first sides 215 of the substrate sections, however the wirebonds may be coupled to first and/or second sections of the substrate 202, depending upon the particular application. In FIG. 2e, a mold compound 210 may be formed over the substrate sections and the plurality of stacked die 204. In FIG. 2f, the PET 203 and glass holder 205 may be removed thus forming the first package 201, and in FIG. 2g, solder balls 230 may be attached on the first package 201 may be coupled to peripheral substrate sections, and a second package 220 may be attached to the first package 201 by using an attachment process 240, such as a surface mount process, for example.

The second package 220 may comprise at least one through mold interconnect (TMI) solder ball/interconnect structure 232 that may be disposed on a conductive pad/terminal on/within the second package substrate 222. The TMI solder ball(s) 232 may be disposed on a peripheral portion of the second package substrate 222, in an embodiment, and may be disposed adjacent sidewalls of a molding compound 210. In an embodiment, there may be two or more TMI solder balls 232 adjacent each other in the periphery region of the second package substrate 222. A second package die 224 may be embedded at least partially within the molding compound 210, and the TMI solder balls 232 may be disposed adjacent the die 204 on the substrate 222, and may be disposed within an opening of the molding compound 210, in an embodiment.

The second package 220 further includes a package die 224, through silicon vias 228 and conductive interconnect structures 236. In FIG. 2h, a POP assembly 200 is formed by joining the first package 201 to the second package 220, wherein solder joints 231 are disposed between the first and second packages 201, 220. The POP package/assembly 200 may be coupled to a board 250 by a plurality of substrate solder balls 248. The board may comprise a motherboard, or any other suitable type of board, in an embodiment.

The board 250 may comprise any suitable type of circuit board or other substrate capable of providing electrical communication between one or more of the various components disposed on the board 250. In one embodiment, for example, the board 250 may comprise a printed circuit board (PCB) comprising multiple metal layers separated from one another by a layer of dielectric material and interconnected by electrically conductive vias. Any one or more of the metal layers may be formed in a desired circuit pattern to route—perhaps in conjunction with other metal layers—electrical signals between the components coupled with the board 250. However, it should be understood that the disclosed embodiments are not limited to the above-described PCB and, further, that board 250 may comprise any other suitable substrate.

The PoP assembly 200 includes the first package 201 and the second package 220, wherein each of the first and second packages 201, 220 may include any suitable device/die or combination of devices. According to one embodiment, first package 201 includes one or more processing systems and the second package 220 includes one or more memory devices. In another embodiment, first package 201 includes one or more processing systems and the second package 220 comprises a wireless communications system (or, alternatively, includes one or more components of a communications system).

In a further embodiment, the first package 201 includes one or more processing systems and the second package 220 includes a graphics processing system. The PoP assembly 200 may comprise part of any type of computing system, such as a hand-held computing system (e.g., a cell phone, smart phone, music player, etc.), mobile computing system (e.g., a laptop, nettop, tablet, etc.), a desktop computing system, or a server. In one embodiment, the PoP assembly 200 comprises a solid-state drive (SSD).

The second package 220 may comprise any suitable package structure. In one embodiment, the second package comprises an IC die 224 disposed on the substrate 222, and is electrically (and perhaps mechanically) coupled with the substrate 222 by a number of interconnects 226. In one embodiment, the die 224 is disposed on the substrate 222 in a flip-chip arrangement, and each of the interconnects 226 may comprise an electrically conductive terminal on the die 224 (e.g., a conductive pad, conductive bump, conductive pillar, or other structure or combination of structures) and a mating conductive terminal on the substrate 222 (e.g., a conductive pad, conductive bump, conductive pillar, or other structure or combination of structures) that are electrically coupled by, for example, a solder reflow process.

The embodiments described herein provide improvement in impedance matching between individual memory in the plurality of stacked memory die, since the wirebond length differences are minimized due to the elimination of the substrate beneath the stacked die. Additionally, by eliminating the underlying substrate and placing the stacked die adjacent substrate sections, on chip hot spots are reduced since heat is dissipated through the molding compound from the top and bottom of the first package. The POP assemblies/package structures of the embodiments herein utilize the area/volume in the center of the POP memory package to create a void/cavity within the memory substrate, so that the stacked die may be housed within the central portion of the first package. Overall POP package Z height reduction is realized by eliminating the memory substrate thickness. In the embodiments, Z height is reduced by the elimination of the first package substrate thickness/height. Improved electrical performance is achieved by reducing variance in impedance mismatch from all stacked die with lowering the height of the highest die to contact pads on adjacent substrate sections.

The number of substrate layers of the first package may vary depending upon design requirements, and the number of substrate layers can be increased while not increasing the Z height of the total package. Increased DRAM bandwidth is achieved by increasing the number of memory die that may be stacked while meeting Z height requirement. Since the substrate is not present below the stacked die, the substrate height does not contribute to the total package Z height. Another advantage of the enclosed embodiments is that steps can be created on inner edges of a memory substrate wherein the stacked die may be flipped in orientation, in order to optimize the wirebonding process/yield for better impedance. Such steps may provide for wirebonding to contact pads located at opposite sides of the substrate. These steps provide for further optimization of process yield to desired impedance requirements. The embodiments enable system form factor miniaturization and device performance enhancement for various applications.

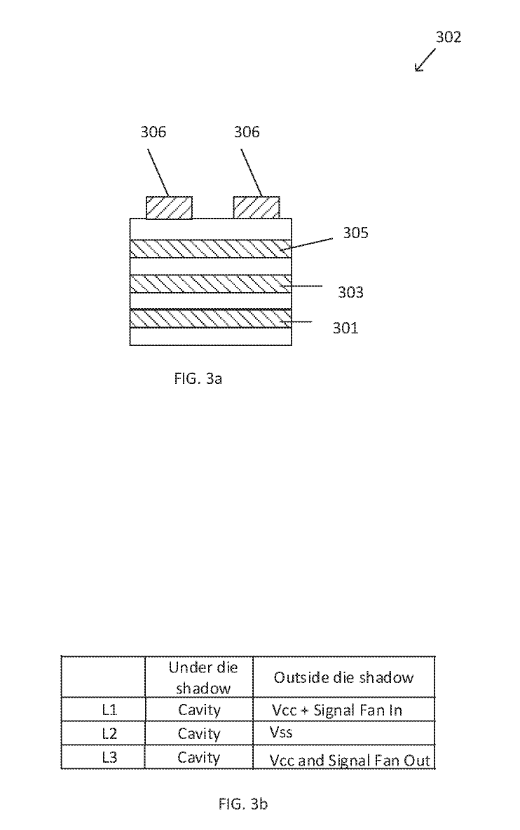

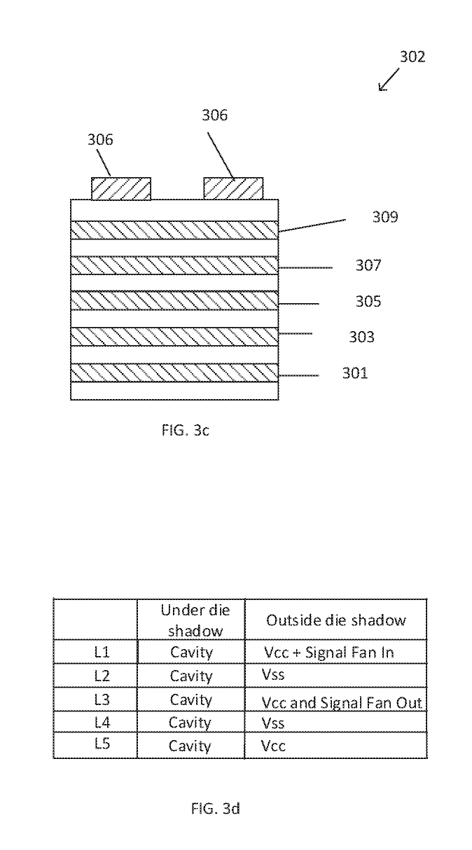

FIGS. 3a-3d depict various substrate layers that may be employed within an upper package, such as within the first package 101 of FIG. 1c, for example. In FIG. 3a, a section of a substrate 302, (such as the first or the second sections 102a, 102b of FIG. 1a, for example) may comprise a first level of metal 301, a second level of metal 303, and a third level of metal 305. Conductive contacts 306 may be disposed on a surface of the substrate 302. In an embodiment, the first level 301 may comprise a Vcc and signal fan in, the second level of metal 303 may comprise Vss, and the third level of metal 305 may comprise a Vcc plus signal fan out. The three levels of metal 301, 303, 305 may be present outside the die shadow, but are not located under the die shadow as shown in the table FIG. 3b, since the die stack is disposed between substrate sections, and is not disposed on the substrate.

In FIG. 3c, a section of a substrate 302, (such as the first or second sections 102a, 102b of FIG. 1a, for example) may comprise a first level of metal 301, a second level of metal 303, a third level of metal 305, a fourth level of metal 307, and a fifth level of metal 309. In an embodiment, the first level 301 may comprise a Vcc and signal fan in, the second level of metal 303 may comprise Vss, the third level of metal 305 may comprise a Vcc plus signal fan out, the fourth level of metal 307 may comprise Vss, and the fifth level of metal may comprise Vcc. The five levels of metal 301, 303, 305, 307, 309 may be present outside the die shadow, but are not located under the die shadow as shown in the table FIG. 3d, since the die stack is disposed between substrate sections, and is not disposed on the substrate. The embodiments herein enable increased dedicated layers for I/O and Vcc.

In prior art POP assemblies, under die shadow area can be underutilized. The embodiments herein locate signal and power routing confined to the area outside of the die shadow. The number of substrate layers can be increased to give dedicated layers/areas for signal routing and power flooding. Increased number of layers are independent of total package Z, providing the flexibility to have more layers for routing. The embodiments achieve required performance for memory especially in high end smartphone market segment while keeping the package small and thin to the lowest possible.

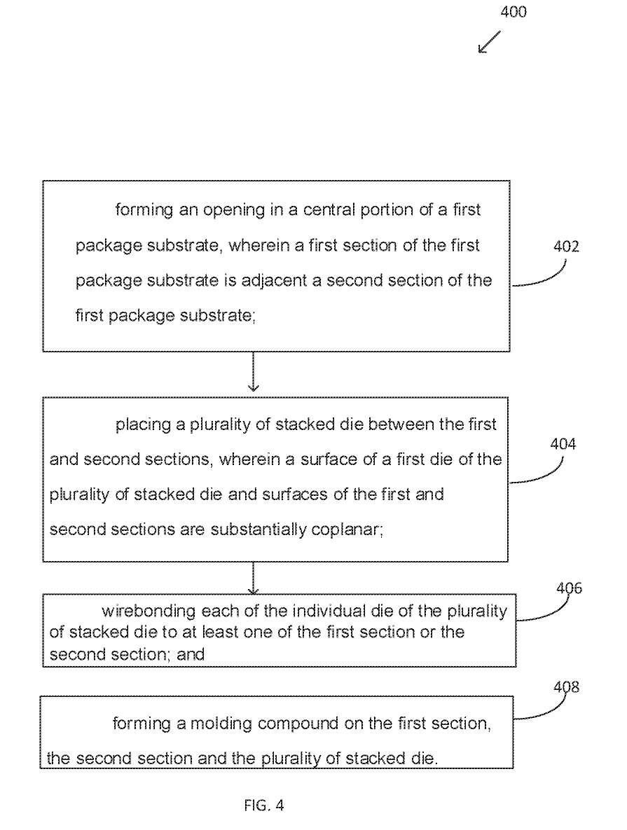

FIG. 4 depicts a method 400 according to embodiments herein. At step 402, an opening may be formed in a central portion of a first package substrate, wherein a first section of the first package substrate is adjacent a second section of the first package substrate. The first package substrate may comprise an upper package of a POP package, in an embodiment. At step 404, a plurality of stacked die may be placed between the first and second sections, wherein a first side of the plurality of stacked die and first sides of the first and second sections are substantially coplanar. The plurality of stacked die may comprise a plurality of memory die, in an embodiment, and some of the individual die may comprise offset footprints from each other. At step 406 each of the individual die of the plurality of stacked die may be wirebonded to at least one of the first section or the second section. At step 408, a molding compound may be formed on the first section, the second section and the plurality of stacked die. In an embodiment, the package substrate may comprise a first package, and the first package may be attached to a second package to form a package on package assembly.

The structures of the embodiments herein may be coupled with any suitable type of structures capable of providing electrical communications between a microelectronic device, such as a die, disposed in package structures, and a next-level component to which the package structures may be coupled (e.g., a circuit board). The device/package structures, and the components thereof, of the embodiments herein may comprise circuitry elements such as logic circuitry for use in a processor die, for example. Metallization layers and insulating material may be included in the structures herein, as well as conductive contacts/bumps that may couple metal layers/interconnects to external devices/layers. In some embodiments the structures may further comprise a plurality of dies, which may be stacked upon one another, depending upon the particular embodiment. In an embodiment, the die(s) may be partially or fully embedded in a package structure.

The various embodiments of the device structures included herein may be used for system on a chip (SOC) products, and may find application in such devices as smart phones, notebooks, tablets, wearable devices and other electronic mobile devices. In various implementations, the package structures may be included in a laptop, a netbook, an ultrabook, a personal digital assistant (PDA), an ultra-mobile PC, a mobile phone, a desktop computer, a server, a printer, a scanner, a monitor, a set-top box, an entertainment control unit, a digital camera, a portable music player, or a digital video recorder, and wearable devices. In further implementations, the package devices herein may be included in any other electronic devices that process data.

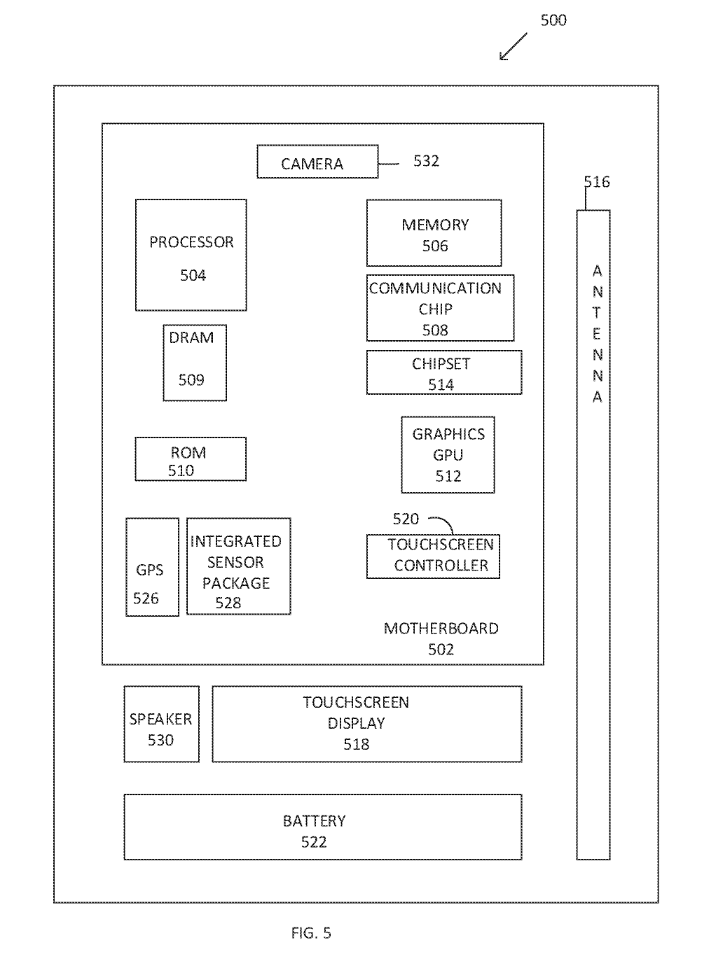

FIG. 5 is a schematic of a computing device 500 that may be implemented incorporating embodiments of the package structures described herein. For example, any suitable ones of the components of the computing device 500 may include, or be included in, package structures/assemblies, such as is depicted in FIG. 1c, wherein the plurality of stacked die are coplanar with substrate sections of a first package of a POP assembly. In an embodiment, the computing device 500 houses a board 502, such as a motherboard 502 for example. The board 502 may include a number of components, including but not limited to a processor 504, an on-die memory 506, and at least one communication chip 508. The processor 504 may be physically and electrically coupled to the board 502. In some implementations the at least one communication chip 508 may be physically and electrically coupled to the board 502. In further implementations, the communication chip 508 is part of the processor 504.

Depending on its applications, computing device 500 may include other components that may or may not be physically and electrically coupled to the board 502, and may or may not be communicatively coupled to each other. These other components include, but are not limited to, volatile memory (e.g., DRAM) 509, non-volatile memory (e.g., ROM) 510, flash memory (not shown), a graphics processor unit (GPU) 512, a chipset 514, an antenna 516, a display 518 such as a touchscreen display, a touchscreen controller 520, a battery 522, an audio codec (not shown), a video codec (not shown), a global positioning system (GPS) device 526, an integrated sensor 528, a speaker 530, a camera 532, compact disk (CD) (not shown), digital versatile disk (DVD) (not shown), and so forth). These components may be connected to the system board 502, mounted to the system board, or combined with any of the other components.

The communication chip 508 enables wireless and/or wired communications for the transfer of data to and from the computing device 500. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 508 may implement any of a number of wireless or wired standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, Ethernet derivatives thereof, as well as any other wireless and wired protocols that are designated as 3G, 4G, 5G, and beyond.

The computing device 500 may include a plurality of communication chips 508. For instance, a first communication chip may be dedicated to shorter range wireless communications such as Wi-Fi and Bluetooth and a second communication chip may be dedicated to longer range wireless communications such as GPS, EDGE, GPRS, CDMA, WiMAX, LTE, Ev-DO, and others. The term “processor” may refer to any device or portion of a device that processes electronic data from registers and/or memory to transform that electronic data into other electronic data that may be stored in registers and/or memory.

In various implementations, the computing device 500 may be a laptop, a netbook, a notebook, an ultrabook, a smartphone, a tablet, a personal digital assistant (PDA), an ultra mobile PC, a wearable device, a mobile phone, a desktop computer, a server, a printer, a scanner, a monitor, a set-top box, an entertainment control unit, a digital camera, a portable music player, or a digital video recorder. In further implementations, the computing device 500 may be any other electronic device that processes data.

Embodiments of the package structures described herein may be implemented as a part of one or more memory chips, controllers, CPUs (Central Processing Unit), microchips or integrated circuits interconnected using a motherboard, an application specific integrated circuit (ASIC), and/or a field programmable gate array (FPGA).

### EXAMPLES

Example 1 is a microelectronic package structure comprising: a first package comprising a first section of a first substrate, wherein the first section comprises a first side and a second side; a second section of the first substrate disposed adjacent the first section, wherein the second section comprises a first side and a second side; a plurality of stacked die disposed between the first section and the second section, wherein a first die of the plurality of stacked die comprises a first side and an opposing second side, and wherein the second side of the first die is coplanar with the second side of the first section and the second side of the second section.

Example 2 includes the microelectronic package structure of example 1, wherein the plurality of die further comprise a second die on the first die, a third die on the second die and a fourth die on the third die.

Example 3 includes the microelectronic package structure of example 2 wherein the first die and third die are wire bonded to the first section of the substrate, and wherein the second die and the fourth die are wirebonded to the second section of the substrate.

Example 4 includes the microelectronic package structure of example 2 wherein a footprint of the first die and a footprint of the third die are offset from a footprint of the second die and a footprint of the fourth die.

Example 5 includes the microelectronic package structure of example 1 wherein the first section of the substrate section and the second section of the substrate do not extend across the length of the first package.

Example 6 includes the microelectronic package structure of example 2 wherein at least one of the first section or the second section comprises a first conductive pad on a first side and a second conductive pad on a second side, wherein the first side and the second side are opposite each other, and wherein the second side is closer to the first die than the first side.

Example 7 includes the microelectronic package structure of claim 6 wherein the first die is physically and electrically coupled to the second conductive pad, and wherein the third die is electrically and physically coupled to the first conductive pad.

Example 8 includes the microelectronic package structure of claim 1 wherein the first package is disposed on a second package, wherein the second package comprises a second package die, and wherein the plurality of stacked die comprises a plurality of stacked memory die.

Example 9 is a method of forming a microelectronic package structure comprising: forming an opening in a central portion of a first package substrate, wherein a first section of the first package substrate is adjacent a second section of the first package substrate; placing a plurality of stacked die between the first section and the second section of the first package substrate, wherein a second side opposite a first side of a first die of the plurality of stacked die, a second side opposite a first side of the first section and a second side opposite a first side of the second section are substantially coplanar; wirebonding each of the individual die of the plurality of stacked die to at least one of the first section or the second section; and forming a molding compound on the first section of the first package substrate, the second section of the first package substrate, and on the plurality of stacked die.

Example 10 includes the method of forming the microelectronic package structure of example 9 further comprising attaching the first package to a second package by using an attachment process.

Example 11 includes the method of forming the microelectronic package structure of example 10 wherein attaching the first package to the second package comprises attaching a first solder ball that is physically and electrically coupled to the first die of the plurality of stacked die to a second solder ball that is physically and electrically coupled to a second die that is coupled to the second package.

Example 12 includes the method of forming the microelectronic package structure of example 9 wherein wirebonding each of the individual die comprises wirebonding at least one of the individual die to one of the first side or the second side of the first section or the second section.

Example 13 includes the method of forming the microelectronic package structure of example 12 wherein at least one of the first section or the second section comprises a stepped structure.

Example 14 includes the method of forming the microelectronic package structure of example 9 wherein the plurality of stacked die comprises a second die on the first die, a third die on the second die and a fourth die on the third die, wherein a footprint of the first die and a footprint of the third die is offset from a foot print of the second die and a footprint of the fourth die.

Example 15 includes the method of forming the microelectronic package structure of example 14 wherein the footprint of the first die and the foot print of the third die are substantially aligned with each other, and wherein the footprint of the second die and the footprint of the fourth die are substantially aligned with each other.

Example 16 includes the method of forming the microelectronic package structure of example 9, wherein the microelectronic package structure comprises a package on package assembly.

Example 17 is a microelectronic system, comprising: a board; a microelectronic package assembly attached to the board, wherein the microelectronic package comprises: a first package, wherein the first package includes a first substrate section and a second substrate section; a plurality of stacked die disposed between the first substrate section and the second substrate section, wherein a surface of a first die of the plurality of stacked die is coplanar with a surface of the first section and with a surface of the second section; and a second package physical and electrically coupled to the first package.

Example 18 includes the microelectronic system of example 17 wherein each individual die of the plurality of stacked die comprise a wirebond between at least one of the first substrate section or the second substrate section of the first package substrate.

Example 19 includes the microelectronic system of example 17 wherein at least one of the first package section or the second package section comprise a first side and a second side, wherein the first side and the second side are opposite each other, and wherein the first side is farther from the first die than the second side.

Example 20 includes the microelectronic system of example 17 wherein the plurality of stacked die comprises a second die on the first die, a third die on the second die, and a fourth die on the third die, wherein at least one of the first die or the second die comprise a wire bond between the first die or the second die and the second side of one of the first section or the second section.

Example 21 includes the microelectronic system of example 17 wherein a height of the first section and a height of the second section is not greater than a height of the plurality of stacked die.

Example 22 includes the microelectronic system of example 20 further comprising wherein a footprint of the first die and a footprint of the third die is offset from a foot print of the second die and a footprint of the fourth die.

Example 23 includes the microelectronic system of example 17 wherein the microelectronic package assembly comprises a package on package assembly.

Example 24 includes the microelectronic system of example 17 wherein the plurality of stacked die comprise a plurality of stacked memory die.

Example 25 includes the microelectronic package system of example 17 wherein the second package comprises a system on a chip.

Although the foregoing description has specified certain steps and materials that may be used in the methods of the embodiments, those skilled in the art will appreciate that many modifications and substitutions may be made. Accordingly, it is intended that all such modifications, alterations, substitutions and additions be considered to fall within the spirit and scope of the embodiments as defined by the appended claims. In addition, the Figures provided herein illustrate only portions of exemplary microelectronic devices and associated package structures that pertain to the practice of the embodiments. Thus the embodiments are not limited to the structures described herein.

1. A microelectronic package structure comprising:
a first package comprising a first section of a first substrate, wherein the first section comprises a first side and a second side;
a second section of the first substrate disposed adjacent the first section, wherein the second section comprises a first side and a second side;
a plurality of stacked die disposed between the first section and the second section, wherein a first die of the plurality of stacked die comprises a first side and an opposing second side, and wherein the second side of the first die is coplanar with the second side of the first section and the second side of the second section.

2. The microelectronic package structure of claim 1, wherein the plurality of die further comprise a second die on the first die, a third die on the second die and a fourth die on the third die.

3. The microelectronic package structure of claim 2 wherein the first die and third die are wire bonded to the first section of the substrate, and wherein the second die and the fourth die are wirebonded to the second section of the substrate.

4. The microelectronic package structure of claim 2 wherein a footprint of the first die and a footprint of the third die are offset from a footprint of the second die and a footprint of the fourth die.

5. The microelectronic package structure of claim 1 wherein the first section of the substrate section and the second section of the substrate do not extend across the length of the first package.

6. The microelectronic package structure of claim 2 wherein at least one of the first section or the second section comprises a first conductive pad on a first side and a second conductive pad on a second side, wherein the first side and the second side are opposite each other, and wherein the second side is closer to the first die than the first side.

7. The microelectronic package structure of claim 6 wherein the first die is physically and electrically coupled to the second conductive pad, and wherein the third die is electrically and physically coupled to the first conductive pad.

8. The microelectronic package structure of claim 1 wherein the first package is disposed on a second package, wherein the second package comprises a second package die, and the plurality of stacked die comprises a plurality of stacked memory die.

9. A method of forming a microelectronic package structure comprising:
forming an opening in a central portion of a first package substrate, wherein a first section of the first package substrate is adjacent a second section of the first package substrate;
placing a plurality of stacked die between the first section and the second section of the first package substrate, wherein a second side opposite a first side of a first die of the plurality of stacked die, a second side opposite a first side of the first section and a second side opposite a first side of the second section are substantially coplanar;
wirebonding each of the individual die of the plurality of stacked die to at least one of the first section or the second section; and
forming a molding compound on the first section of the first package substrate, the second section of the first package substrate, and on the plurality of stacked die.

10. The method of forming the microelectronic package structure of claim 9 further comprising attaching the first package to a second package by using an solder reflow process.

11. The method of forming the microelectronic package structure of claim 10 wherein attaching the first package to the second package comprises attaching a first solder ball that is physically and electrically coupled to the first die of the plurality of stacked die to a second solder ball that is physically and electrically coupled to a second die that is coupled to the second package.

12. The method of forming the microelectronic package structure of claim 9 wherein wirebonding each of the individual die comprises wirebonding at least one of the individual die to one of the first side or the second side of the first section or the second section.

13. The method of forming the microelectronic package structure of claim 12 wherein at least one of the first section or the second section comprises a stepped structure.

14. The method of forming the microelectronic package structure of claim 9 wherein the plurality of stacked die comprise a second die on the first die, a third die on the second die and a fourth die on the third die, wherein a footprint of the first die and a footprint of the third die is offset from a foot print of the second die and a footprint of the fourth die.

15. The method of forming the microelectronic package structure of claim 14 wherein the footprint of the first die and the foot print of the third die are substantially aligned with each other, and wherein the footprint of the second die and the footprint of the fourth die are substantially aligned with each other.

16. The method of forming the microelectronic package structure of claim 9, wherein the microelectronic package structure comprises a package on package assembly.

17. A microelectronic system, comprising:
a board;
a microelectronic package assembly attached to the board, wherein the microelectronic package comprises:
a first package, wherein the first package includes a first substrate section and a second substrate section;
a plurality of stacked die disposed between the first substrate section and the second substrate section, wherein a surface of a first die of the plurality of stacked die is coplanar with a surface of the first section and with a surface of the second section; and
a second package physical and electrically coupled to the first package.

18. The microelectronic system of claim 17 wherein each individual die of the plurality of stacked die comprise a wirebond between at least one of the first substrate section or the second substrate section of the first package substrate.

19. The microelectronic system of claim 17 wherein at least one of the first package section or the second package section comprise a first side and a second side, wherein the first side and the second side are opposite each other, and wherein the first side is farther from the first die than the second side.

20. The microelectronic system of claim 17 wherein the plurality of stacked die comprises a second die on the first die, a third die on the second die, and a fourth die on the third die, wherein at least one of the first die and the second die comprise a wire bond between the first die or the second die and the second side of one of the first section or the second section.

21. The microelectronic system of claim 17 wherein a height of the first section and a height of the second section is not greater than a height of the plurality of stacked die.

22. The microelectronic system of claim 20 further comprising wherein a footprint of the first die and a footprint of the third die is offset from a foot print of the second die and a footprint of the fourth die.

23. The microelectronic system of claim 17 wherein the microelectronic package assembly comprises a package on package assembly.

24. The microelectronic system of claim 17 wherein the plurality of stacked die comprise a plurality of stacked memory die.

25. The microelectronic package system of claim 24 wherein the second package comprises a system on a chip.
